(19) United States
(12) Patent Application Publication
(10) Pub. No.: US 2026/0223699 A1
(43) Pub. Date: Jul. 30, 2026

(54) HIGH VOLTAGE ISOLATION PACKAGE

(71) Applicant: Texas Instruments Incorporated, Dallas, TX (US)

(72) Inventors: Bernardo Gallegos, McKinney, TX (US); Shawn O'Connor, McKinney, TX (US)

(21) Appl. No.: 19/039,119

(22) Filed: Jan. 28, 2025

(51) Int. Cl. H10W 70/65; H10W 70/05; H10W 70/60; H10W 70/63; H10W 70/69; H10W 72/00; H10W 74/10; H10W 90/00

(52) U.S. Cl. CPC H10W 70/65; H10W 70/05; H10W 70/611; H10W 70/635; H10W 70/69; H10W 72/884; H10W 74/111; H10W 90/734; H10W 90/754

(57) ABSTRACT

A semiconductor package comprises a package substrate. The package substrate comprises a first metal pad and a second metal pad on a first surface of the package substrate. The semiconductor package also comprises a first layer on the first surface of the package substrate. The first layer comprises one or more trenches. The semiconductor package also comprises a first die on the first layer and coupled to the first metal pad. The semiconductor package also comprises a second die on the first layer and coupled to the second metal pad. The semiconductor package further comprises a mold compound covering the first die, the second die, and the package substrate. The mold compound is in contact with the one or more trenches. The one or more trenches locates between the first die and the second die. The semiconductor package is suitable for high voltage isolation package applications.

### FIELD

The present disclosure relates generally to high voltage isolation packages, and more particularly to metal pad and solder resist design to improve performance and reliability of high voltage isolation packages.

### BACKGROUND

Many circuits include circuitry in multiple voltage domains, such as low voltage logic circuitry in a low voltage domain, and communication driver circuits in a high voltage domain. Such circuits are usually integrated within high voltage isolation packages. A high voltage isolation package is usually designed with a large separation between the low voltage domain and the high voltage domain to prevent arching and improve working voltage. Such design is typically realized by increasing external lead distances, which can be accomplished on package substrate, and increasing internal distance between the low voltage domain and the high voltage domain inside the high voltage isolation package. The latter usually results in an increased size and cost of the high voltage isolation packages.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a semiconductor package. The semiconductor package comprises a package substrate comprising a first metal pad and a second metal pad on a first surface of the package substrate. The semiconductor package also comprises a first layer on the first surface of the package substrate. The first layer comprises one or more trenches. The semiconductor package also comprises a first die on the first layer and coupled to the first metal pad. The semiconductor package also comprises a second die on the first layer and coupled to the second metal pad. The semiconductor package further comprises a mold compound covering the first die, the second die, and the package substrate and in contact with the one or more trenches. The one or more trenches locates between the first die and the second die.

Disclosed aspects include a method of forming a semiconductor package. The method comprises providing a package substrate comprising a first metal pad and a second pad on a first surface of the package substrate. The method also comprises forming a first layer on the first surface of the package substrate and patterning the first layer to expose the first metal pad and the second metal pad and form one or more trenches in the first layer. The method also comprises attaching a first die and a second die on the first layer. The method further comprises covering the first die, the second die, and the package substrate with a mold compound. The one or more trenches locates between the first die and the second die.

Disclosed aspects include a device. The device comprises a printed circuit board (PCB). The device further comprises a semiconductor package on the PCB. The semiconductor package comprises a package substrate comprising a first metal pad and a second metal pad on a first surface of the package substrate. The semiconductor package also comprises a first layer on the first surface of the package substrate. The first layer comprises one or more trenches. The semiconductor package also comprises a first die on the first layer and coupled to the first metal pad. The semiconductor package also comprises a second die on the first layer and coupled to the second metal pad. The semiconductor package further comprises a mold compound covering the first die, the second die, and the package substrate and in contact with the one or more trenches. The one or more trenches locates between the first die and the second die.

### BRIEF DESCRIPTION OF THE DRAWINGS

Reference will now be made to the accompanying drawings, which are not necessarily drawn to scale, wherein:

FIG. 1A is a 3D view of an example semiconductor package with metal pad and solder resist design to improve performance and reliability in accordance with certain aspects of present disclosure;

FIG. 1B is a top perspective view of the example semiconductor package of FIG. 1A;

FIG. 1C is a bottom perspective view of the example semiconductor package of FIG. 1A;

FIG. 1D is a cross-section view of the example semiconductor package of FIG. 1A;

FIG. 2 illustrates a fabrication process for an example semiconductor package with metal pad and solder resist design to improve performance and reliability in accordance with certain aspects of present disclosure;

FIGS. 3A-3D illustrate cross-section views of the example semiconductor package in each process step of FIG. 2;

FIG. 4 a 3D view of an example device including a semiconductor package with metal pad and solder resist design to improve performance and reliability in accordance with certain aspects of present disclosure.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems, and/or components are hereinafter described in the context of functions which in some cases result from configuration and/or interconnection of various structures when circuitry is powered and operating. In the following discussion and in the claims, the terms “including,” “includes,” “having,” “has,” “with,” or variants thereof are intended to be inclusive in a manner similar to the term “comprising,” and thus should be interpreted to mean “including, but not limited to.”

Unless otherwise stated, “about,” “approximately,” or “substantially” preceding a value means +/- 10 percent of the stated value. One or more structures, features, aspects, components, etc., may be referred to herein as first, second, third, etc., such as first and second terminals, first, second, and third dies, etc., for ease of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

In a high voltage isolation package, ground pads for a high voltage domain and a low voltage domain would require a large separation between them to prevent arching and improve working voltage. Mold compound used to encapsulate the high voltage isolation package needs to possess good adhesion with package substrate to improve reliability, which would usually require a large contact area between the mold compound and the package substrate. These requirements would result in increased package size and manufacturing cost. Thus, a high voltage isolation package, which can satisfy the ground pad separation and the mold compound adhesion requirements without increasing the package size, needs to be developed.

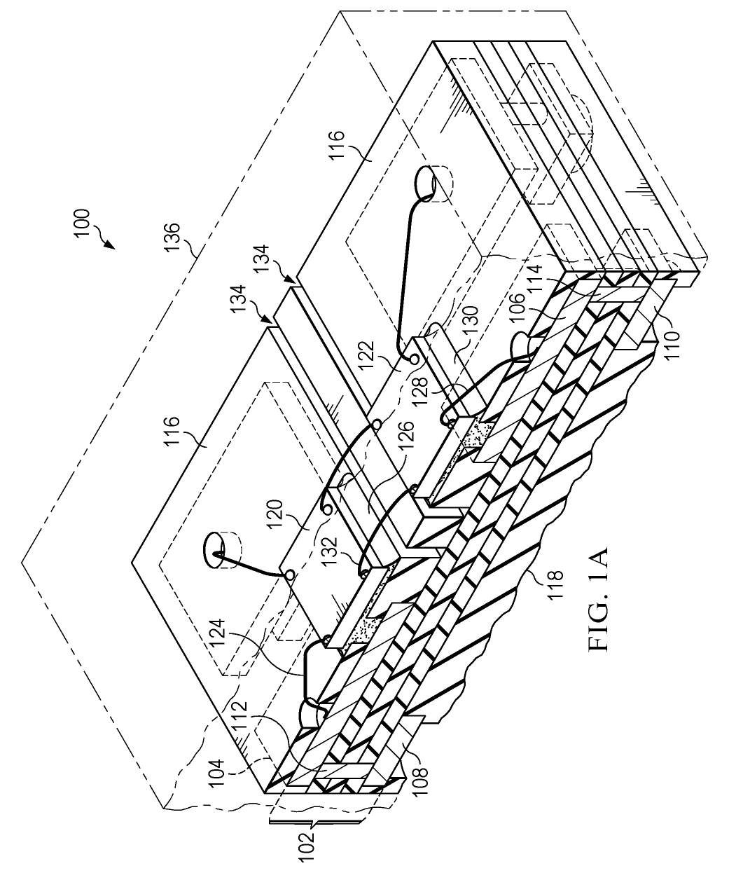

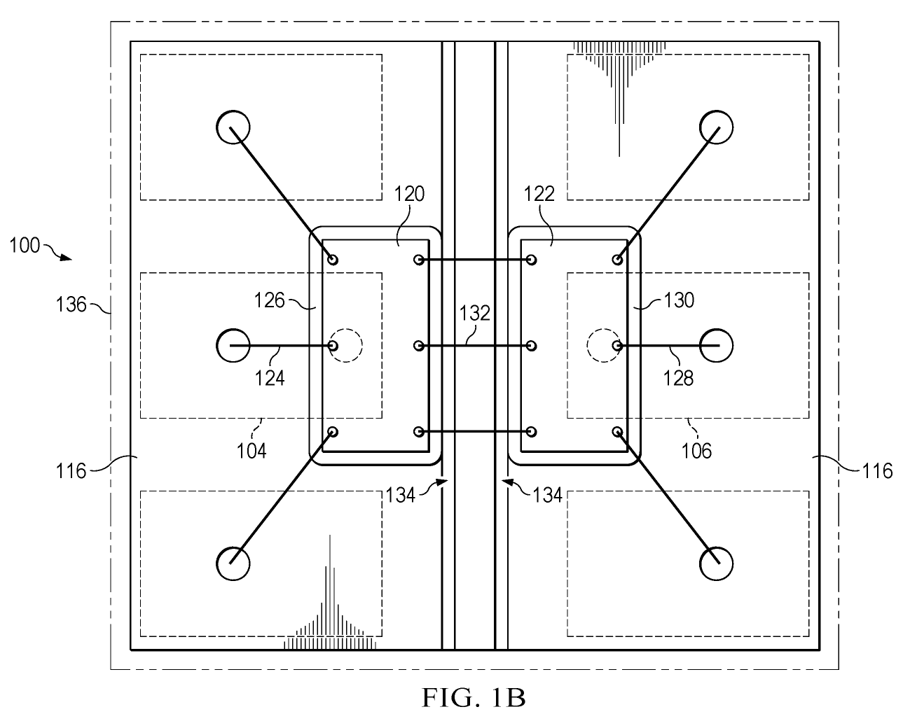

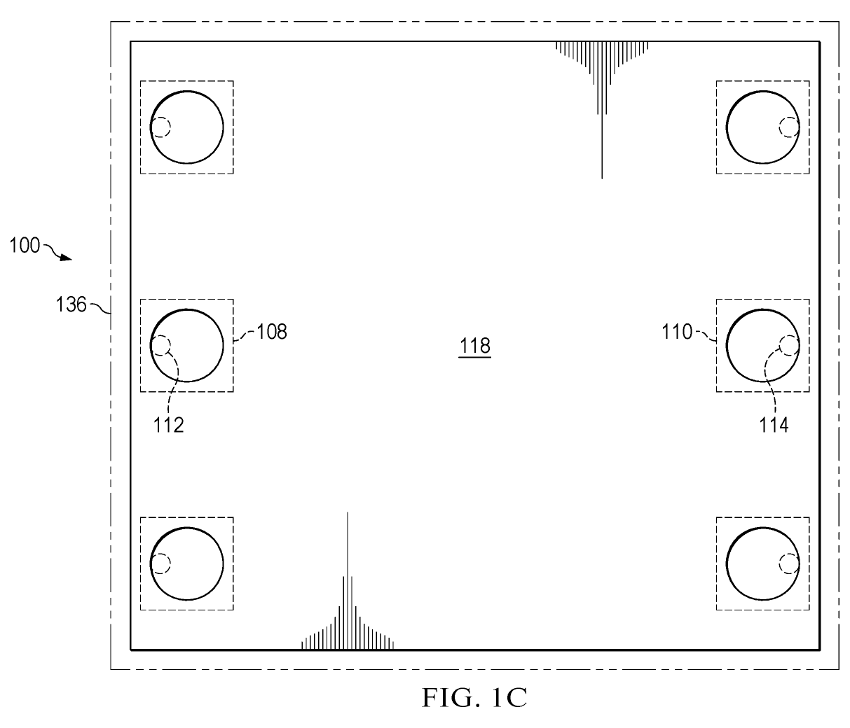

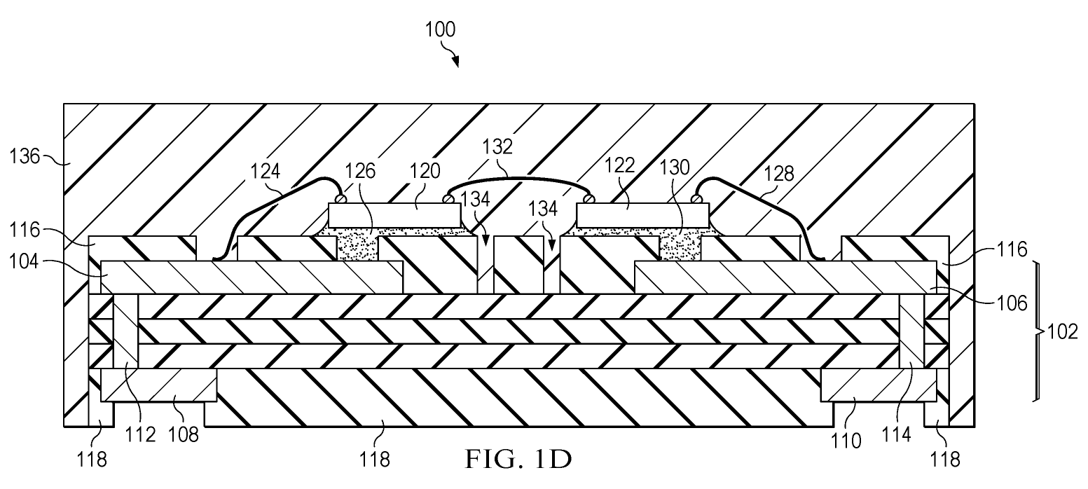

Disclosed aspects include a semiconductor package with metal pad and solder resist design to improve performance and reliability. FIG. 1A is a 3D view of a semiconductor package 100 with metal pad and solder resist design to improve performance and reliability in accordance with certain aspects of present disclosure. FIG. 1B is a top perspective view of the semiconductor package 100 of FIG. 1A. FIG. 1C is a bottom perspective view of the semiconductor package 100 of FIG. 1A. And FIG. 1D is a cross-section view of the semiconductor package 100 of FIG. 1A. The semiconductor package 100 comprises a package substrate 102. The package substrate 102 comprises a first metal pad 104 and a second metal pad 106 on a first surface of the package substrate 102. The first metal pad 104 and the second metal pad 106 may comprises copper (Cu). The first metal pad 104 may be a ground pad for a high voltage domain. The second metal pad 106 may be a ground pad for a low voltage domain. The package substrate 102 also comprises a third metal pad 108 and a fourth metal pad 110 on a second surface of the package substrate 102 opposite the first surface. The third metal pad 108 and the fourth metal pad 110 may comprise Cu. The package substrate 102 further comprises a first via 112 and a second via 114. The first via 112 and the second via 114 may comprise Cu. The first via 112 couples the first metal pad 104 to the third metal pad 108. The second via 114 couples the second metal pad 106 to the fourth metal pad 110.

The semiconductor package 100 also comprises a first solder resist layer 116 on the first surface of the package substrate 102 and a second solder resist layer 118 on the second surface of the package substrate 102. The first solder resist layer 116 and the second solder resist layer 118 may comprise polymer or epoxy material. A portion of the first solder resist layer 116 locates between the first metal pad 104 and the second metal pad 106. A portion of the second solder resist layer 118 locates between the third metal pad 108 and the fourth metal pad 110.

The semiconductor package 100 also comprises a first die 120 and a second die 122 on the first solder resist layer 116. The first die 120 may operate in the high voltage domain at a first voltage. The first die 120 may couple to the first metal pad 104 via a first bond wire 124. The first die 120 may also couple to the first metal pad 104 via a first die attach material 126. The first die 120 may couple to the first solder resist layer 116 via the first die attach material 126. The first die attach material 126 may comprise an electrically conductive die attach material or an electrically non-conductive die attach material. The second die 122 may operate in the low voltage domain at a second voltage. The first voltage may be higher than the second voltage. The second die 122 may couple to the second metal pad 106 via a second bond wire 128. The second die 122 may also couple to the second metal pad 106 via a second die attach material 130. The second die 122 may couple to the first solder resist layer 116 via the second die attach material 130. The second die attach material 130 may comprise an electrically conductive die attach material or an electrically non-conductive die attach material. The first die 120 may couple to the second die 122 via a third bond wire 132. Even though two dies are shown to be included in the semiconductor package 100, the semiconductor package 100 may include any number of dies. The first solder resist layer 116 comprises one or more trenches 134 between the first die 120 and the second die 122. For example, two trenches are shown in the first solder resist layer 116 between the first die 120 and the second die 122. The first die 120 has an edge closer to the one or more trenches 134 and the edge is a first distance away from a first trench of the one or more trenches 134. The first metal pad 104 has an edge closer to the one or more trenches 134 and the edge is a second distance away from the first trench of the one or more trenches 134. The first distance is smaller than the second distance. The second die 122 has an edge closer to the one or more trenches 134 and the edge is a third distance away from the first trench of the one or more trenches 134. The second metal pad 106 has an edge closer to the one or more trenches 134 and the edge is a fourth distance away from the first trench of the one or more trenches 134. The third distance is smaller than the fourth distance. Thus, a distance between the first metal pad 104 and the second metal pad 106 is greater than a distance between the first die 120 and the second die 122. Such design improves separation between the first metal pad 104 and the second metal pad 106, resulting in improved performance and reliability of the semiconductor package 100 without changing package size.

The semiconductor package 100 further comprises a mold compound 136 covering the package substrate 102, the first solder resist layer 116, the second solder resist layer 118, the first die 120, and the second die 122. The mold compound 136 is in contact with the one or more trenches 134. The one or more trenches 134 provides more contact area for the mold compound 136 with the first solder resist layer 116 to enhance their adhesion. Such design improves adhesion between the mold compound 136 and the first solder resist layer 116, resulting in improved reliability of the semiconductor package 100 without changing package size. The semiconductor package 100 would be suitable for high voltage isolation package applications.

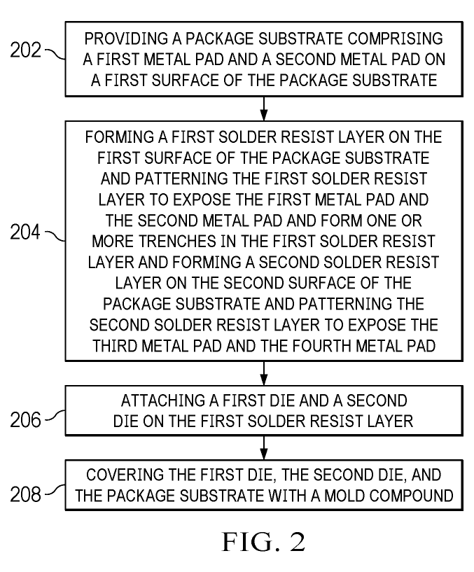

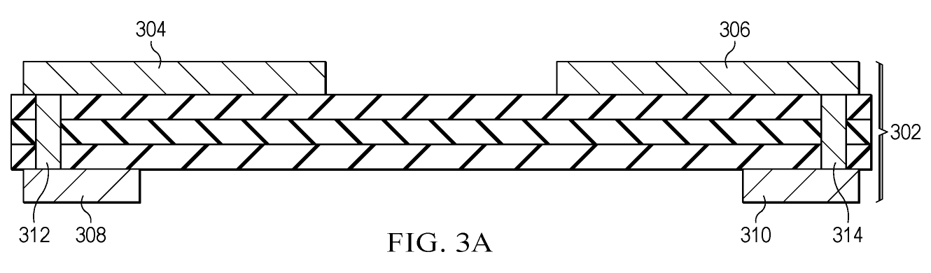

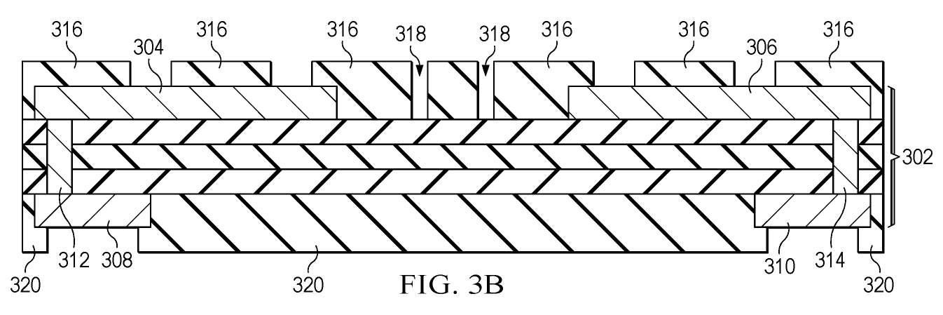

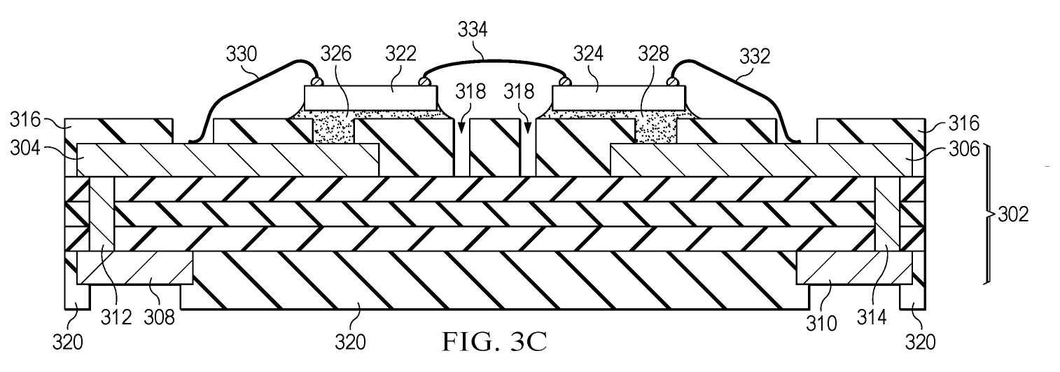

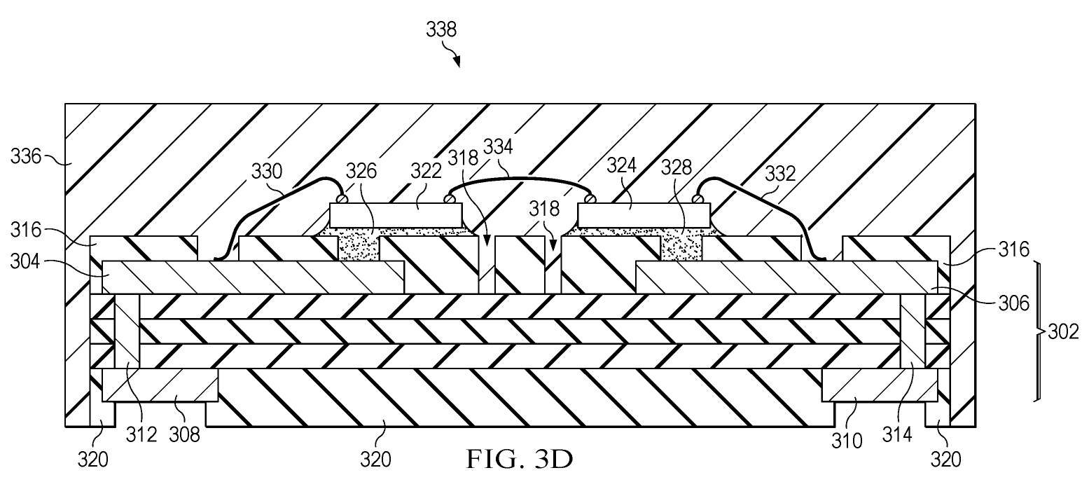

FIG. 2 illustrates a fabrication process for a semiconductor package with metal pad and solder resist design to improve performance and reliability in accordance with certain aspects of present disclosure. FIG. 3A to FIG. 3D illustrate cross-section views of the semiconductor package in each process step of FIG. 2. Accordingly, FIG. 2 and FIG. 3A to FIG. 3D are described in parallel.

Step 202 comprises providing a package substrate comprising a first metal pad and a second metal pad on a first surface of the package substrate. As shown in FIG. 3A, a package substrate302 comprises a first metal pad 304 and a second metal pad 306 on a first surface of the package substrate 302. The first metal pad 304 and the second metal pad 306 may comprise Cu. The package substrate 302 also comprises a third metal pad 308 and a fourth metal pad 310 on a second surface of the package substrate 302 opposite the first surface. The third metal pad 308 and the fourth metal pad 310 may comprise Cu. The package substrate 302 further comprises a first via 312 and a second via 314. The first via 312 and the second via 314 may comprise Cu. The first via 312 couples the first metal pad 304 to the third metal pad 308. The second via 314 couples the second metal pad 306 to the fourth metal pad 310.

Step 204 comprises forming a first solder resist layer on the first surface of the package substrate and patterning the first solder resist layer to expose the first metal pad and the second metal pad and form one or more trenches in the first solder resist layer. As shown in FIG. 3B, a first solder resist layer 316 is formed on the first surface of the package substrate 302. The first solder resist layer 316 is patterned to form a plurality of openings and one or more trenches 318 in the first solder resist layer 316. The plurality of openings comprises openings to expose the first metal pad 304 and the second metal pad 306. The plurality of openings may be formed by a lithography process. The one or more trenches 318 may be formed by a lithography process together with the plurality of openings. On the other hand, the one or more trenches 318 may be formed by a laser ablation process separately. The one or more trenches 318 formed by laser ablation could have a smaller dimension and a higher aspect ratio compared with the one or more trenches 318 formed by lithography. Step 204 also comprises forming a second solder resist layer on the second surface of the package substrate and patterning the second solder resist layer to expose the third metal pad and the fourth metal pad. As shown in FIG. 3B, a second solder resist layer 320 is formed on the second surface of the package substrate 302. The second solder resist layer 320 is patterned to form a plurality of openings in the second solder resist layer 320. The plurality of openings comprises openings to expose the third metal pad 308 and the fourth metal pad 310. The plurality of openings may be formed by a lithography process.

Step 206 comprises attaching a first die and a second die on the first solder resist layer. As shown in FIG. 3C, a first die 322 and a second die 324 are on the first solder resist layer 316. The first die 322 may couple to the first solder resist layer 316 via a first die attach material 326. The first die attach material 326 may comprise an electrically conductive die attach material or an electrically non-conductive die attach material. The second die 324 may couple to the first solder resist layer 316 via a second die attach material 328. The second die attach material 328 may comprise an electrically conductive die attach material or an electrically non-conductive die attach material. The first die 322 may couple to the first metal pad 304 via a first bond wire 330. The first die 322 may also couple to the first metal pad 304 via the first die attach material 326. The second die 324 may couple to the second metal pad 306 via a second bond wire 332. The second die 324 may also couple to the second metal pad 306 via the second die attach material 328. The first die 322 may couple to the second die 324 via a third bond wire 334. The one or more trenches 318 locates between the first die 322 and the second die 324.

Step 208 comprises covering the first die, the second die, and the package substrate with a mold compound. As shown in FIG. 3D, a mold compound 336 covers the first die 322, the second die 324, and the package substrate 302 to form a semiconductor package 338. The mold compound 336 is in contact with the one or more trenches 318.

The first die 322 may operate in a high voltage domain at a first voltage. The second die 324 may operate in a low voltage domain at a second voltage. The first voltage may be higher than the second voltage. The first metal pad 304 may be a ground pad for the high voltage domain. The second metal pad 306 may be a ground pad for the low voltage domain. The first die 322 has an edge closer to the one or more trenches 318 and the edge is a first distance away from a first trench of the one or more trenches 318. The first metal pad 304 has an edge closer to the one or more trenches 318 and the edge is a second distance away from the first trench of the one or more trenches 318. The first distance is smaller than the second distance. The second die 324 has an edge closer to the one or more trenches 318 and the edge is a third distance away from the first trench of the one or more trenches 318. The second metal pad 306 has an edge closer to the one or more trenches 318 and the edge is a fourth distance away from the first trench of the one or more trenches 318. The third distance is smaller than the fourth distance. Thus, a distance between the first metal pad 304 and the second metal pad 306 is greater than a distance between the first die 322 and the second die 324. Such design improves separation between the first metal pad 304 and the second metal pad 306, resulting in improved performance and reliability of the semiconductor package 338 without changing package size. The one or more trenches 318 provides more contact area for the mold compound 336 with the first solder resist layer 316 to enhance their adhesion. Such design improves adhesion between the mold compound 336 and the first solder resist layer 316, resulting in improved reliability of the semiconductor package 338 without changing package size. The semiconductor package 338 would be suitable for high voltage isolation package applications.

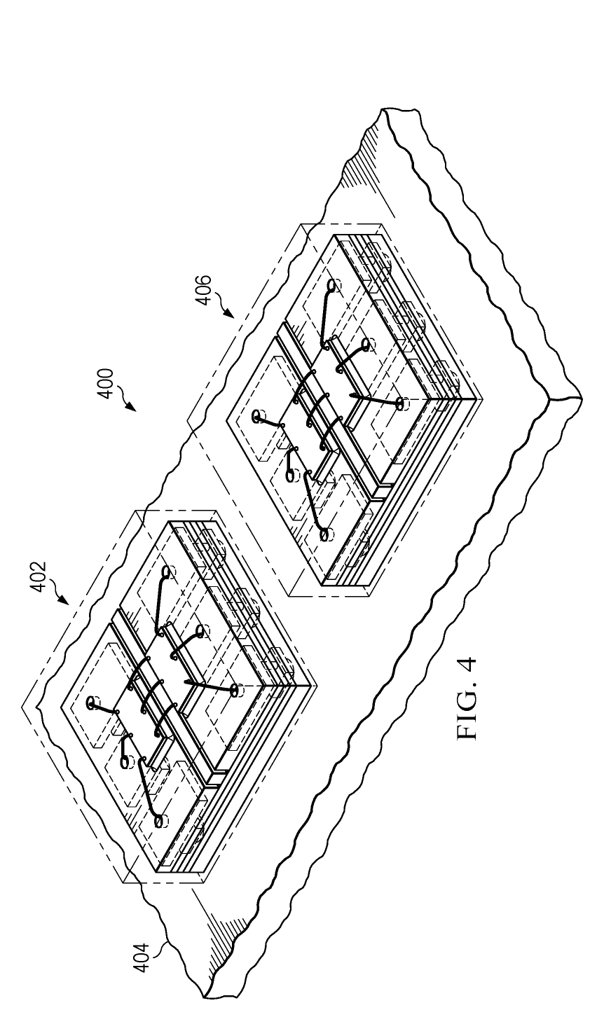

FIG. 4 is a 3D view of a device 400 including a semiconductor package 402 with metal pad and solder resist design to improve performance and reliability in accordance with certain aspects of present disclosure. The device 400 comprises a printed circuit board (PCB) 404. The semiconductor package 402 is mounted on the PCB 404. The semiconductor package 402 is similar to the semiconductor package 100 with similar metal pad and solder resist design and is suitable for high voltage isolation package applications. The device 400 further comprises another semiconductor package 406 mounted on the PCB 404. The semiconductor packages 402 and 406 operate together to perform functions of the device 400.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A semiconductor package, comprising:
a package substrate, comprising a first metal pad and a second metal pad on a first surface of the package substrate;
a first layer on the first surface of the package substrate, comprising one or more trenches;
a first die on the first layer and coupled to the first metal pad;
a second die on the first layer and coupled to the second metal pad; and
a mold compound covering the first die, the second die, and the package substrate and in contact with the one or more trenches, wherein the one or more trenches locates between the first die and the second die.

2. The semiconductor package of claim 1, wherein the first metal pad is coupled to a first voltage and the second metal pad is coupled to a second voltage, and wherein the first voltage is higher than the second voltage.

3. The semiconductor package of claim 1, wherein the first die is coupled to the first metal pad via a bond wire.

4. The semiconductor package of claim 3, wherein the first die is further coupled to the first metal pad via an electrically conductive die attach material.

5. The semiconductor package of claim 3, wherein the first die is further coupled to the first metal pad via an electrically non-conductive die attach material.

6. The semiconductor package of claim 1, wherein an edge of the first die closer to the one or more of trenches is a first distance away from a first trench of the one or more trenches and an edge of the first metal pad closer to the one or more trenches is a second distance away from the first trench of the one or more trenches, and wherein the first distance is smaller than the second distance.

7. The semiconductor package of claim 6, wherein an edge of the second die closer to the one or more trenches is a third distance away from the first trench of the one or more trenches and an edge of the second metal pad closer to the one or more trenches is a fourth distance away from the first trench of the one or more trenches, and wherein the third distance is smaller than the fourth distance.

8. The semiconductor package of claim 1, wherein the package substrate further comprises a third metal pad and a fourth metal pad on a second surface of the package substrate.

9. The semiconductor package of claim 8, wherein the first metal pad, the second metal pad, the third metal pad, and the fourth metal pad comprise copper.

10. The semiconductor package of claim 8, wherein the package substrate further comprises a via coupling the first metal pad to the third metal pad.

11. The semiconductor package of claim 1, wherein the first layer comprises polymer.

12. A method of forming a semiconductor package, comprising:
providing a package substrate comprising a first metal pad and a second metal pad on a first surface of the package substrate;
forming a first layer on the first surface of the package substrate and patterning the first layer to expose the first metal pad and the second metal pad and form one or more trenches in the first layer;
attaching a first die and a second die on the first layer; and
covering the first die, the second die, and the package substrate with a mold compound, wherein the one or more trenches locates between the first die and the second die.

13. The method of claim 12, wherein the one or more trenches is formed by a lithography process.

14. The method of claim 12, wherein the one or more trenches is formed by a laser ablation process.

15. The method of claim 12, wherein the first metal pad is coupled to a first voltage and the second metal pad is coupled to a second voltage, and wherein the first voltage is higher than the second voltage.

16. The method of claim 12, wherein the first die is coupled to the first metal pad via a bond wire.

17. The method of claim 16, wherein the first die is further coupled to the first metal pad via an electrically conductive die attach material.

18. The method of claim 16, wherein the first die is further coupled to the first metal pad via an electrically non-conductive die attach material.

19. The method of claim 12, wherein an edge of the first die closer to the one or more trenches is a first distance away from a first trench of the one or more trenches and an edge of the first metal pad closer to the one or more trenches is a second distance away from the first trench of the one or more trenches, and wherein the first distance is smaller than the second distance.

20. The method of claim 19, wherein an edge of the second die closer to the one or more trenches is a third distance away from the first trench of the one or more trenches and an edge of the second metal pad closer to the one or more trenches is a fourth distance away from the first trench of the one or more trenches, and wherein the third distance is smaller than the fourth distance.

21. The method of claim 12, wherein the first layer comprises polymer.

22. A device, comprising:
a printed circuit board (PCB); and
a semiconductor package on the PCB, the semiconductor package comprising:
a package substrate, comprising a first metal pad and a second metal pad on a first surface of the package substrate;
a first layer on the first surface of the package substrate, comprising one or more trenches;
a first die on the first layer and coupled to the first metal pad;
a second die on the first layer and coupled to the second metal pad; and
a mold compound covering the first die, the second die, and the package substrate and in contact with the one or more trenches, wherein the one or more trenches locates between the first die and the second die.
